(19) United States
(12) Patent Application Publication
(10) Pub. No.: US 2011/0061811 A1
(43) Pub. Date: Mar. 17, 2011

(54) PLASMA PROCESSING APPARATUS

(75) Inventors: Toru Ito, Yamanashi (JP); Sumie Segawa, Yamanashi (JP)

(73) Assignee: TOKYO ELECTRON LIMITED, Tokyo (JP)

(21) Appl. No.: 12/920,731

(22) PCT Filed: Feb. 26, 2009
(86) PCT No.: PCT/JP2009/053510

§ 371 Date: Nov. 29, 2010

(30) Foreign Application Priority Data
Mar. 7, 2008 (JP) 2008-057883

(51) Int. Cl. H01L 21/3065

(52) U.S. Cl. 156/345.28

(57) ABSTRACT

A plasma monitoring device is provided with a measuring section, and a coaxial cable connected to the measuring section. One end of the coaxial cable is inserted into a plasma generating region in a processing chamber. A leading end portion of the coaxial cable is permitted to be a probe, and the portion is in a state where the core cable is exposed. The measuring section detects frequency distribution of electromagnetic waves existing in plasma detected by the probe portion of the coaxial cable, and displays the detected frequency distribution.

### TECHNICAL FIELD

The present invention relates to a plasma processing apparatus for a plasma process of a substrate.

### BACKGROUND

In a conventional manufacturing process of a semiconductor device, there has been used a plasma processing apparatus that is configured to generate a plasma of a processing gas in a processing chamber and carries out a plasma process of a substrate disposed in the processing chamber by the plasma. The substrate is, for example, a semiconductor wafer or a glass substrate for a liquid crystal display device. The plasma process is, for example, an etching process or a film forming process.

In the above plasma processing apparatus, the condition of the process carried out on the substrate depends on a plasma condition. Thus, there has been a known technique, for example, which measures an electron density in a plasma by measuring the frequencies of electromagnetic waves absorbed by electrons in the plasma (for example, refer to Patent document 1).

Patent document 1: Japanese Unexamined Patent Publication No. 2004-103264.

### SUMMARY OF THE INVENTION

As mentioned above, in a conventional technique, a plasma condition is monitored by measuring the electron density of the plasma. However, all of plasma conditions cannot be represented by only one factor such as the electron density. Thus, there has been a need for improving the plasma monitoring method capable of monitoring plasma conditions in detail from various points of view.

The present invention is developed to correspond to the problems of the conventional technique and provide a plasma processing apparatus that can monitor the plasma conditions in detail from various view points.

### MEANS TO SOLVE THE PROBLEMS

The plasma processing apparatus described in claim 1 includes a processing chamber configured to dispose a substrate, a gas supply unit configured to supply a predetermined processing gas into the processing chamber, an exhausting unit configured to exhaust a gas from the processing chamber, a plasma generating unit configured to generate plasma of the processing gas in the processing chamber, and a plasma monitoring device that includes a coaxial cable and a measuring unit. In particular, the coaxial cable has a probe disposed in the processing chamber, and the measuring unit connected to the coaxial cable is configured to detect a frequency distribution of electromagnetic waves in the plasma detected by the probe.

The plasma processing apparatus described in claim 2 is the plasma processing apparatus described in claim 1, and has the measuring unit configured to detect at least one or more of a different frequency component and a sideband component of the plasma.

The plasma processing apparatus described in claim 3 is the plasma processing apparatus described in claim 1, and includes a plurality of processing chambers, and a controller controlling a plasma condition in each of the plurality of processing chambers to be consistent with each other based on the results detected by the plasma monitoring device.

The plasma processing apparatus described in claim 4 is the plasma processing apparatus described in claim 3, and has the controller configured to control at least one or more of the gas supply unit, the exhausting unit, and the plasma generating unit.

The plasma processing apparatus described in claim 5 includes a processing chamber configured to dispose a substrate, a gas supply unit configured to supply a processing gas having a predetermined flow rate into the processing chamber, an exhausting unit configured to set up a predetermined vacuum level in the processing chamber, a plasma generating unit, including a high-frequency power source, configured to generate plasma of the processing gas in the processing chamber, a measuring unit configured to detect at least one or more of a different frequency component and a sideband component of the plasma by inserting a probe into the plasma, and a control unit configured to control at least one or more of the gas supply unit, the exhausting unit, and the plasma generating unit based on the results detected by the measuring unit.

### BRIEF DESCRIPTION OF THE DRAWINGS

FIG. 1 shows a schematic view illustrating the configuration of a plasma etching apparatus, according to one embodiment of the present invention.

FIG. 2 is an enlarged view illustrating the configuration of a coaxial cable.

FIG. 3 is a graph illustrating an example of a plasma monitoring result.

FIG. 4 is a graph illustrating an example of a plasma monitoring result.

FIG. 5 is a graph illustrating an example of a plasma monitoring result.

FIG. 6 is a graph illustrating an example of a plasma monitoring result.

FIG. 7 is a graph illustrating an example of a plasma monitoring result.

FIG. 8 shows a schematic view illustrating the configuration of a plasma processing apparatus, according to another embodiment of the present invention.

### DETAILED DESCRIPTION OF THE INVENTION

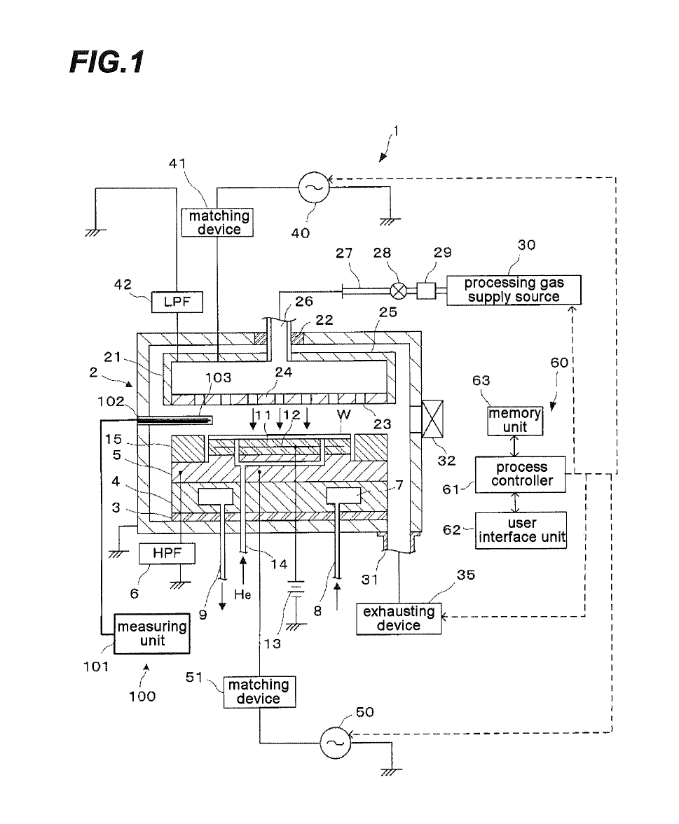

Hereinafter, exemplary embodiments of the present invention will be described with reference to the accompanied drawings. FIG. 1 shows a schematic view illustrating the configuration of a plasma etching apparatus as a plasma processing apparatus, according to one embodiment of the present invention.

A plasma etching apparatus 1 comprises a capacitive coupling type plasma etching apparatus having a parallel structure, which includes upper and lower electrode plates being parallel to face each other and a power source being connected thereto for plasma generation.

Plasma etching apparatus 1 includes, for example, a processing chamber (a processing vessel) 2 molded as a cylindrical shape having an aluminum anodized surface and grounded. A susceptor supporter 4 of substantially circumferential shape is provided in the lower part of processing chamber 2 to dispose an object to be processed such as, for example, a semiconductor wafer W, by means of an insulating plate 3 such as ceramics and so on. A susceptor 5 working as a lower electrode is provided on the susceptor supporter 4. A high-pass filter (HPF) 6 is connected to the susceptor 5.

A refrigerant chamber 7 is provided in the susceptor supporter 4. A refrigerant is introduced via a refrigerant inlet pipe 8, circulated in the refrigerant chamber 7, and discharged via a refrigerant outlet pipe 9, thereby the coldness of the refrigerant is transferred to the semiconductor wafer W via the susceptor 5 and the temperature of the semiconductor wafer W is controlled to a desired level.

The susceptor 5 is formed as a disc-like shape of which the upper center part has a convex shape. An electrostatic chuck 11 having substantially the same shape as the semiconductor wafer W is provided on the susceptor 5. The electrostatic chuck 11 includes an electrode 12 disposed between insulators. A direct current power source 13 connected to electrode 12 applies, for example, a 1.5 kV of direct current voltage, thereby the electrostatic chuck 11 electrostatically attracts the semiconductor wafer W by, for example, a coulomb force.

A gas passage 14 configured to supply a heat transfer medium (for example He gas etc.) to the back surface of the semiconductor wafer W is provided in insulating plate 3, susceptor supporter 4, susceptor 5, and electrostatic chuck 11. The coldness of susceptor 5 is transferred to the semiconductor wafer W via the heat transfer medium and the temperature of the semiconductor wafer W is maintained to a predetermined level.

At the upper end of the peripheral portion of susceptor 5, an annular focus ring 15 is provided so as to surround the semiconductor wafer W disposed on electrostatic chuck 11. Focus ring 15 is made of a conductive material such as silicon and improves the etching uniformity.

At the upper side of susceptor 15, an upper electrode 21 is provided to face susceptor 5 in parallel. Upper electrode 21 is supported at the upper side of processing chamber 2 by an insulating material 22. The upper electrode 21 comprises an electrode plate 24 and an electrode supporter 25 being made of a conductive material and supporting electrode plate 24. Electrode plate 24 is made of an electric conductor or a semiconductor such as Si or SiC, and has a plurality of discharge holes 23. Electrode plate 24 forms an opposite plane against susceptor 5.

A gas inlet 26 provided at the center of electrode supporter 25 of upper electrode 21 is connected to a gas inlet pipe 27. A processing gas supply source 30 is connected to gas inlet pipe 27 via a valve 28 and a mass flow controller 29. The etching gas for the plasma etching process is supplied from processing gas supply source 30.

An exhausting pipe 31 is connected to the lower part of processing chamber 2 and an exhausting device 35 is connected to exhausting pipe 31. Exhausting device 35 includes a vacuum pump such as a turbo molecular pump and is capable of degassing processing chamber 2 to a predetermined level of reduced pressure atmosphere, for example, to a predetermined pressure of 1 Pa or less. A gate valve 32 is provided at the sidewall of processing chamber 2. The semiconductor wafer W is transferred between processing chamber 2 and a load-lock chamber (not shown) adjacent to processing chamber 2 in an open state of gate valve 32.

A first high-frequency power source 40 having a frequency range of 50 MHz to 150 MHz is connected to upper electrode 21, and a matching device 41 is disposed between first high-frequency power source 40 and upper electrode 21. A low-pass filter (LPF) 42 is connected to upper electrode 21. A high density plasma in a desirable dissociation state can be formed in processing chamber 2 by applying the high frequency energy.

A second high-frequency power source 50 is connected to susceptor 5 devised as a lower electrode, and a matching device 51 is disposed at the feeding line. Second high-frequency power source 50 has a frequency range lower than that of first high-frequency power source 40. An appropriate ionic action can be made to the semiconductor wafer W as an object to be processed without causing damage to the semiconductor wafer W by applying the frequency range of second high-frequency power source 50. It is desirable that second high-frequency power source 50 has a frequency range of, for example, 1 MHz to 20 MHz.

A plasma monitoring device 100 is provided to plasma etching apparatus 1. Plasma monitoring device 100 includes a measuring unit 101 and a coaxial cable 102 connected to measuring unit 101. One end of coaxial cable 102 is inserted into a plasma generation area of processing chamber 2. The portion of coaxial cable 102 disposed in processing chamber 2 is covered with a quartz pipe 103. Quartz pipe 103 prevents the semiconductor wafer W from being mixed with the metal impurities coming from coaxial cable 102 when the plasma etching process of the semiconductor wafer W is being performed in processing chamber 2. Thus, when the plasma monitoring is performed experimentally without processing the semiconductor wafer W, the plasma monitoring can be performed without quartz pipe 103, i.e., with coaxial cable 102 to be exposed.

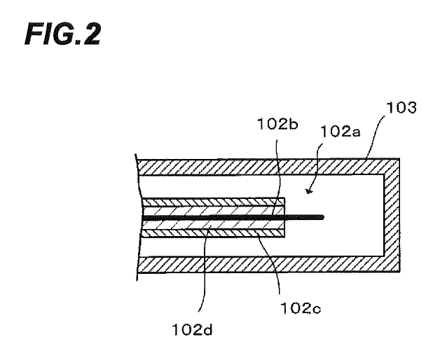

As shown in FIG. 2, a front end portion of the coaxial cable 102 disposed in processing chamber 2 is provided with a probe 102a, and the portion is in the state where a core wire (inner conductor) 102b made of conductor materials such as Aluminum is exposed. An outer conductor 102c such as a copper pipe is provided in the peripheral portion of coaxial cable 102, and an insulator 102d made of resins is provided between the core wire (inner conductor) 102b and the outer conductor 102c.

Measuring unit 101 connected to coaxial cable 102 includes an oscilloscope or a spectrum analyzer which has an FFT (Fast Fourier Transform) analysis function. Measuring unit 101 is configured to detect a frequency distribution of electromagnetic waves in the plasma, which is detected by probe 102a of coaxial cable 102, and display the detected frequency distribution.

As shown in FIG. 1, the operation of plasma etching apparatus 1 is generally controlled by a controller 60. Controller 60 is provided with a process controller 61 including a CPU for controlling each part of plasma etching apparatus 1, a user interface unit 62, and a memory unit 63.

User interface unit 62 includes a keyboard for allowing a process operator to perform an input operation of commands in order to manage plasma etching apparatus 1 or a display for visually displaying the operation conditions of plasma etching apparatus 1.

Memory unit 63 stores a recipe that stores control programs (software) or process condition data for performing various processes in plasma etching apparatus 1 under the control of process controller 61. If necessary, a certain recipe is called from memory unit 63 by a command from user interface unit 62 and performed in process controller 61, thereby performing a desired process in plasma etching apparatus 1 under the control of process controller 61. The recipe of control programs or process condition data can be used in the form stored in a computer-readable storage medium (for example, a hard disk, CD, a flexible disk, a semiconductor memory etc.) or in on-line by frequent-transmission via other devices such as a dedicated circuit.

When the plasma etching process of the semiconductor wafer W is performed by plasma etching apparatus 1, gate valve 32 is opened first, and then, the semiconductor wafer W is transferred into processing chamber 2 from the load-lock chamber (not shown), and is disposed on electrostatic chuck 11. A direct current voltage is applied from direct current power source 13, and the semiconductor wafer W is electrostatically attracted on the electrostatic chuck 11. Subsequently, gate valve 32 is closed, and processing chamber 2 is evacuated to a predetermined vacuum level by exhausting device 35.

Thereafter, the valve 28 is opened, a predetermined etching gas is introduced to a hollow center portion of upper electrode 21 from processing gas supply source 30 via gas inlet pipe 27 and gas inlet 26 while the flow rate of the etching gas is controlled by mass flow controller 29. The predetermined etching gas is uniformly discharged to the semiconductor wafer W via discharge hole 23 of electrode plate 24, as shown with the arrows in FIG. 1.

Then, the pressure in the processing chamber 2 is maintained to a predetermined level. Subsequently, a high-frequency power having a predetermined frequency is applied to upper electrode 21 from first high-frequency power source 40, and a high-frequency electric field is generated between upper electrode 21 and susceptor 5 devised as a lower electrode, thereby dissociating the etching gas to generate a plasma state.

Meanwhile, from second high-frequency power source 50, a high-frequency power having a lower frequency than first high-frequency power source 40 is applied to susceptor 5 devised as a lower electrode. Thus, ions of the plasma are applied to the side of susceptor 5 and the etching anisotropy can be improved by the ion assist.

When the predetermined plasma etching process is completed, the supply of the high-frequency power and the processing gas is stopped, and the semiconductor wafer W is unloaded from processing chamber 2 in the reverse order from the order described above.

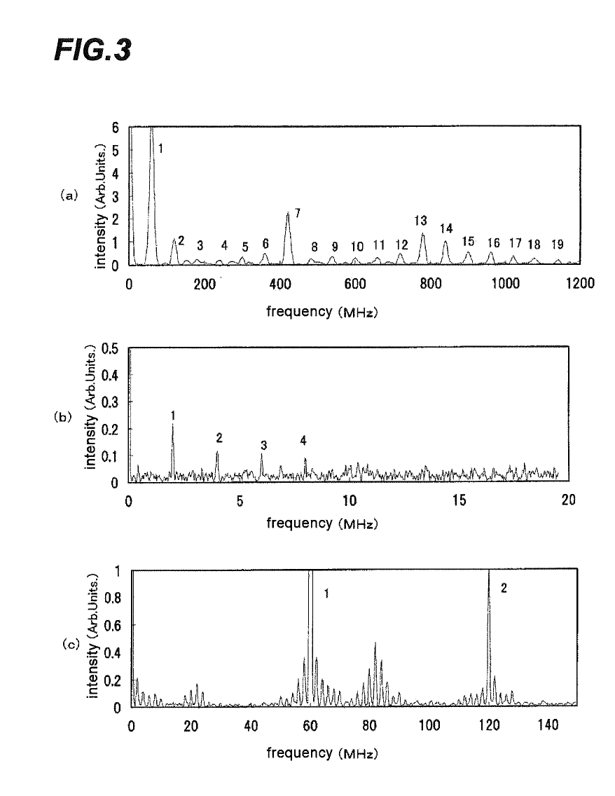

In the above etching process, plasma monitoring is performed by plasma monitoring device 100 when the plasma is generated in processing chamber 2. At this time, as shown in FIG. 3, a frequency distribution (spectrum) of electromagnetic waves detected by probe 102a inserted into processing chamber 2 is indicated as a graph which has a vertical axis of intensity and a horizontal axis of frequency in measuring unit 101.

FIG. 3 shows the plasma monitoring condition monitored by plasma monitoring device 100 when the plasma is generated with the condition of processing gas: Ar=350 sccm, pressure: 13.3 Pa (100 mTorr), and high-frequency wave: 60 MHz/2 MHz=1500/1000 W. In this case, as shown FIG. 3 (a), a higher frequency of 60 MHz produces eighteen (2nd to 19th) peaks of harmonics, each of which has an integer multiple of 60 MHz, other than peak 1 of 60 MHz. As shown in FIG. 3 (b), a lower frequency of 2 MHz produces three (2nd to 4th) peaks of harmonics, each of which has an integer multiple of 2 MHz, other than peak 1 of 2 MHz.

FIG. 3 (c) is a schematic expansion view of a part of FIG. 3 (a). Around peak 1 and peak 2, there exist a plurality of peaks, called sideband, obtained by adding and subtracting an integer multiple of the lower frequency of 2 MHz to and from the higher frequency of 60 MHz. Around 80 MHz between the peak 1 (60 MHz) and peak 2 (120 MHz) and 20 MHz, there are unknown different frequency component peaks.

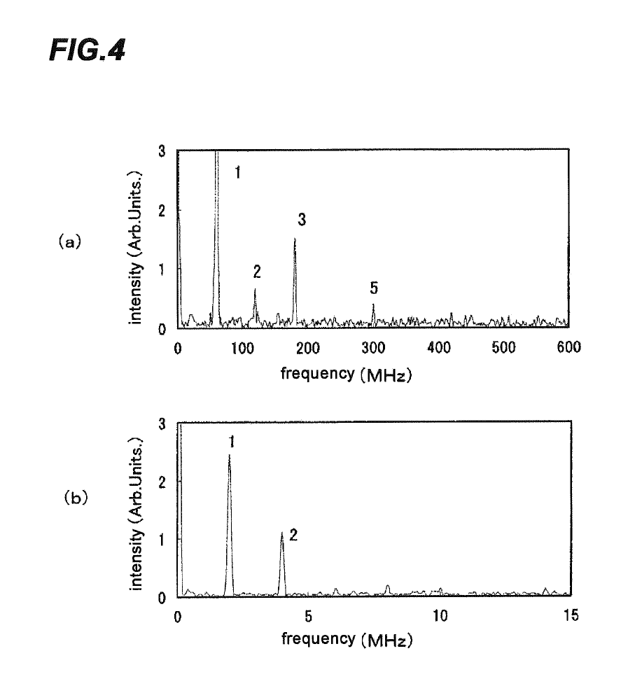

FIG. 4 shows the plasma monitoring condition monitored by plasma monitoring device 100 when the plasma is generated on the conditions of processing gas: Ar/O₂=500/500 sccm, pressure: 26.6 Pa (200 mTorr), and high-frequency wave: 60 MHz/2 MHz=2000/1000 W. In this case, as shown in FIG. 4 (a), the higher frequency of 60 MHz produces three peaks of harmonics, which are peak 2 (120 MHz), peak 3 (180 MHz) and peak 5 (300 MHz), other than the peak 1 of 60 MHz. As shown in FIG. 4 (b), the lower frequency of 2 MHz produces only one peak of harmonics, which is peak 2 (4 MHz), other than the peak 1 of 2 MHz.

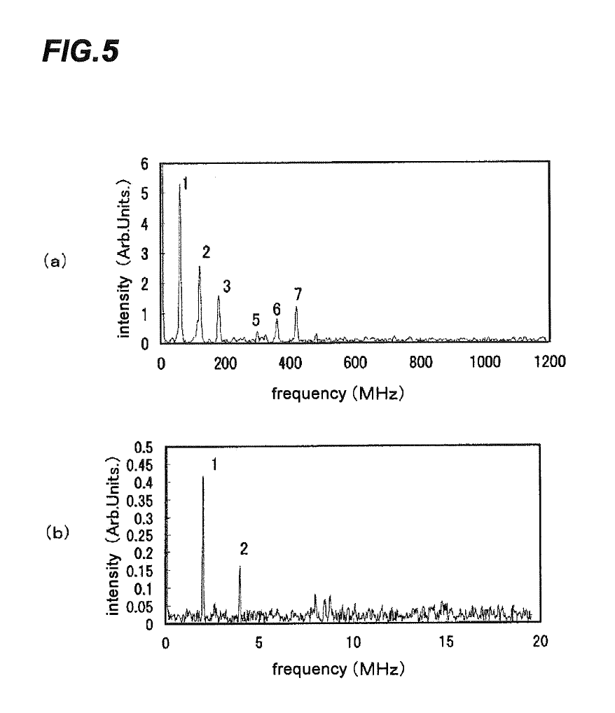

FIG. 5 shows the plasma monitoring condition monitored by plasma monitoring device 100 when the plasma is generated on the conditions of processing gas: CF₄=200 sccm, pressure: 26.6 Pa (200 mTorr), and high-frequency wave: 60 MHz/2 MHz=500/100 W. In this case, as shown in FIG. 5 (a), the higher frequency of 60 MHz produces five peaks of harmonics, which are peak 2 (120 MHz), peak 3 (180 MHz), peak 5 (300 MHz), peak 6 (360 MHz) and peak 7 (420 MHz), other than the peak 1 of 60 MHz. As shown in FIG. 5 (b), the lower frequency of 2 MHz produces only one peak of harmonics, which is peak 2 (4 MHz), other than the peak 1 of 2 MHz.

As described above, if there are differences in the type of used processing gas, flow rate, pressure and power of the high-frequency wave, the results of the plasma monitoring by plasma monitoring device 100 have different positions and heights of the peaks.

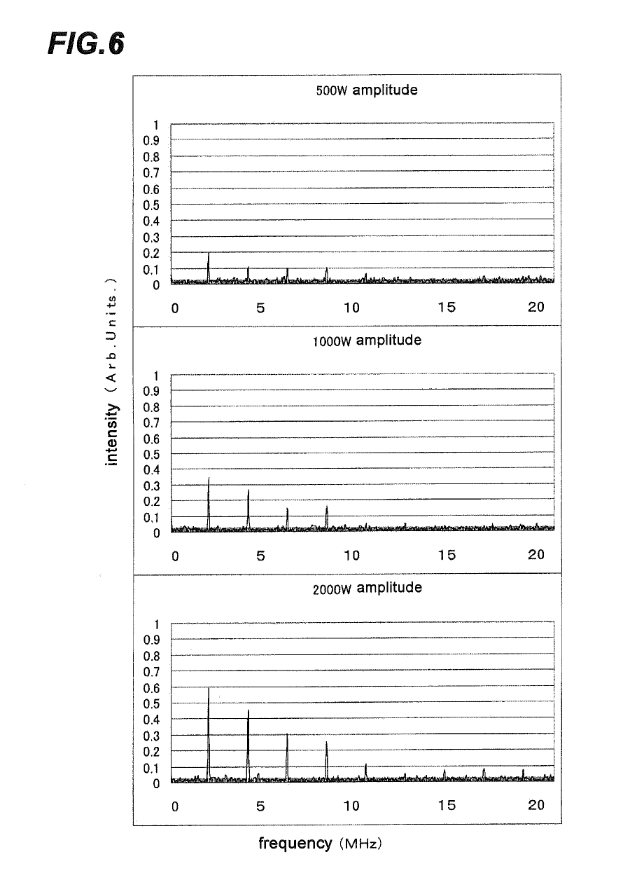

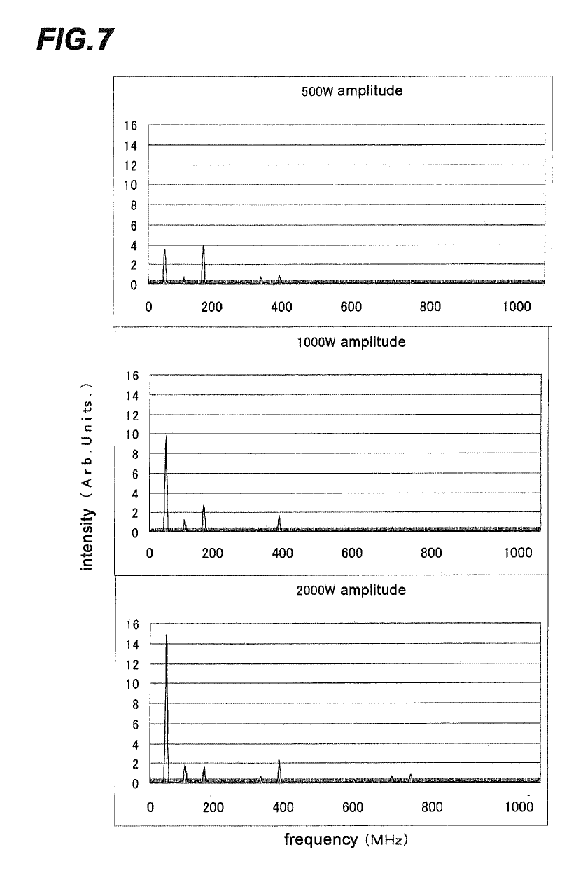

FIG. 6 shows the plasma monitoring condition monitored by plasma monitoring device 100 when the plasma is generated on the conditions of processing gas: Ar=350 sccm, pressure: 13.3 Pa (100 mTorr), and high-frequency wave: 60 MHz/2 MHz=1000/500, 1000, 2000 W. In this case, the applied power of the high-frequency wave of 2 MHz is 500 W, 1000 W, and 2000 W in the upper, middle and lower graph of FIG. 6, respectively. Also, FIG. 7 shows the plasma monitoring condition monitored by plasma monitoring device 100 when the plasma is generated on the conditions of processing gas: Ar=350 sccm, pressure: 13.3 Pa (100 mTorr), and high-frequency wave: 60 MHz/2 MHz=500, 1000, 2000/0 W. In this case, the applied power of the high-frequency wave of 60 MHz is 500 W, 1000 W, and 2000 W in the upper, middle and lower graph of FIG. 7, respectively.

As known from FIG. 6, there are peaks of harmonics at 2 MHz, 4 MHz, 6 MHz, and 8 MHz. When the spectrum intensity is 2 MHz, the intensity of harmonics increases with proportional to the electric power, specifically, about 0.2 (Arb. Units.) at 500 W of power, about 0.4 (Arb. Units.) at 1000 W of power, and about 0.6 (Arb. Units.) at 1500 W of power. In the same manner, when the spectrum intensity is 60 MHz, as shown in FIG. 7, there are peaks of harmonics at 60 MHz, 120 MHz, and 180 MHz, and the intensity of harmonics increases with proportional to the electric power. As shown in FIGS. 6 and 7, if the gas type, gas flow rate, and pressure are the same and only the applied power of high-frequency wave is different, the positions of peak are substantially the same but the heights of peaks increase with proportional to the electric power. Thus, the condition of applying a high-frequency power can be detected based on the heights of peaks.

In the case that there are many harmonics of 60 MHz and 2 MHz shown in FIGS. 3 (a) and 3 (b), or the case that there are the sideband and different frequency component as shown in FIG. 3. (c), it is assumed that there is a great loss of high-frequency power due to the inefficient use of the applied high-frequency power. In other words, upon comparison of FIGS. 3 (a) and 4 (a), while there are more (e.g., nineteen) peaks of harmonics of 60 MHz and the high-frequency power is dispersed in FIG. 3 (a), it can be said that there are less (e.g., four) peaks of harmonics and the loss of high-frequency power is very small in FIG. 4 (a). Upon comparison of FIGS. 3 (b) and 4 (b), while there are four peaks of harmonics of 2 MHz in FIG. 3 (b), there are two peaks of harmonics in FIG. 4. (b). Also, upon comparison of the intensity of peaks, while the same high-frequency power of 1000 W is applied to lower electrode 5, the intensity in FIG. 4 (b) is 10 times of FIG. 3 (b). In the process conditions shown in FIG. 3, the loss of high-frequency power applied to lower electrode 5 is large. As described above and in FIG. 3, in the case that there are many harmonics or there are sidebands and different frequency components, there is a large loss of high-frequency power due to the inefficient use of the applied high-frequency power. Thus, a plasma process can be performed in an efficient and speedy manner by controlling the plasma generation condition (for example, at least one of supplying condition of processing gas, exhausting condition, and applying condition of high-frequency power) to be the monitoring condition as shown in FIGS. 4 and 5.

If plasma monitoring is continuously performed by plasma monitoring device 100, it is possible to detect the occurrence of some troubles in devices and the change in the generation condition of plasma due to the consumption of consumable parts. In this case, for example, if the peak of a high-frequency wave component in a lower frequency side is lowered, a decrease in etching rate is expected. Thus, the decrease in etching rate can be avoided by taking an action such as increasing of the high-frequency power of the lower frequency side.

It is also possible to evaluate the differences in a plurality of devices based on the plasma monitoring results monitored by plasma monitoring device 100. In this case, for example, the evaluation can be easily and readily performed by monitoring the plasma during the plasma generation, rather than by actually performing the process and measuring the process results using SEM.

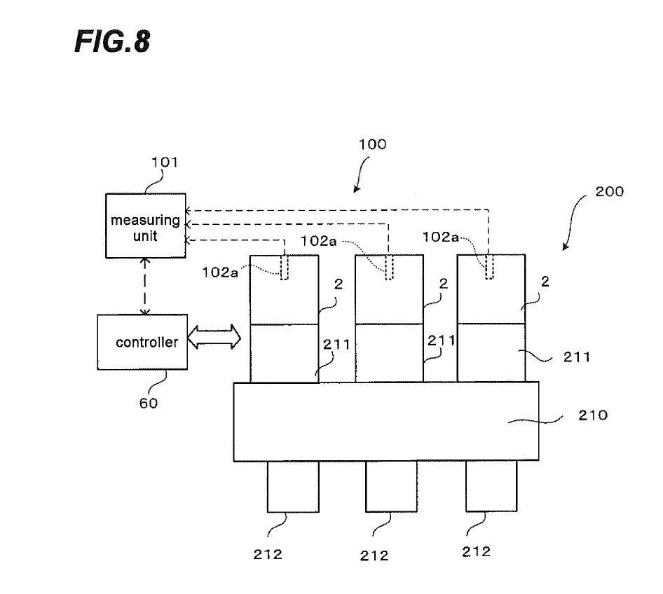

As shown in FIG. 8, for example, the evaluation of differences in devices and the reduction of these differences can be performed in each processing chamber 2 of plasma processing apparatus 200, in which a plurality of processing chambers 2 (three chambers in FIG. 8) are connected to one transfer unit 210 for transferring semiconductor wafers in the atmosphere via each load-lock chamber 211.

In this case, probe 102a of plasma monitoring device 100 as described above is provided in each processing chamber 2, and controller 60 controls plasma conditions in each processing chamber 2 to be consistent with each other based on the plasma monitoring results measured by probe 102a and measuring unit 101. With these features, the difference in processing condition according to the difference in device of each processing chamber 2 can be reduced. In FIG. 8, the drawing reference numeral 212 indicates a cassette including semiconductor wafers or a disposition unit in which FOUPs are disposed.

As described above, in the case that a plurality of processing chambers 2 are provided, the specific control is performed as, for example, described below. That is, the frequency distribution during actual processing of each processing chamber 2 is obtained in each processing chamber 2, and for example, the spectrum intensities of 60 MHz are compared with each other. The power of high-frequency power, pressure, and flow rate of processing gas are controlled so that the spectrum intensities of 60 MHz are consistent with each other, thereby the plasma conditions in each processing chamber 2 are consistent with each other and the difference in devices can be reduced.

As explained above, according to the present embodiment, the plasma condition can be understood in detail and multilaterally. Also, the present invention is not limited to the embodiment as described above and can be variously modified. For example, the plasma processing apparatus is not limited to the high-frequency applying type having upper and lower electrodes in a parallel plate structure as shown in FIG. 1 and can be applied to various types of plasma processing apparatus.

### INDUSTRIAL APPLICABILITY

The plasma processing apparatus of the present invention can be used in the field of manufacturing semiconductor devices. Thus, the present invention has industrial applicability.

What is claimed is:

1. A plasma processing apparatus comprising:
a processing chamber configured to dispose a substrate;
a gas supply unit configured to supply a predetermined processing gas into the processing chamber;
an exhausting unit configured to exhaust a gas from the processing chamber;
a plasma generating unit configured to generate plasma of the processing gas in the processing chamber; and
a plasma monitoring device including a coaxial cable and a measuring unit,
wherein the coaxial cable has a probe disposed in the processing chamber, and the measuring unit connected to the coaxial cable is configured to detect a frequency distribution of electromagnetic waves in the plasma detected by the probe.

2. The plasma processing apparatus according to claim 1, wherein the measuring unit detects at least one or more of a different frequency component and a sideband component in the plasma.

3. The plasma processing apparatus according to claim 1, wherein the plasma processing apparatus includes a plurality of processing chambers, and a controller controlling plasma conditions in each of the plurality of processing chambers to be consistent with each other.

4. The plasma processing apparatus according to claim 3, wherein the controller controls at least one or more of the gas supply unit, the exhausting unit, and the plasma generating unit.

5. A plasma processing apparatus comprising:
a processing chamber configured to dispose a substrate;
a gas supply unit configured to supply a processing gas having a predetermined flow rate into the processing chamber;
an exhausting unit configured to set up a predetermined vacuum level in the processing chamber;
a plasma generating unit, including a high-frequency power source, configured to generate plasma of the processing gas in the processing chamber;
a measuring unit configured to detect at least one or more of a different frequency component and a sideband component in the plasma by inserting a probe into the plasma; and
a control unit configured to control at least one or more of the gas supply unit, the exhausting unit, and the plasma generating unit based on the results detected by the measuring unit.
